(19) United States
(12) Patent Application Publication
(10) Pub. No.: US 2004/0074602 A1
(43) Pub. Date: Apr. 22, 2004

(54) Plasma etching apparatus

(76) Inventor: Shin-Sang Lee, Sungnam-City (KR)

Correspondence Address: VOLENTINE FRANCOS, P.L.L.C., Suite 150, 12200 Sunrise Valley Drive, Reston, VA, 20191, US

(21) Appl. No.: 10/655,307

(22) Filed: Sep. 5, 2003

(30) Foreign Application Priority Data
Oct. 18, 2002 (KR) 2003-63790

(51) Int. Cl. H01L 21/306

(52) U.S. Cl. 156/345.24

(57) ABSTRACT

A plasma etching apparatus has a processing chamber in which a manufacturing process takes place, a monitoring window made of transparent material and disposed in one side of the chamber, and an optical end point detector that detects the end point of the process through the monitoring window. The monitoring window has a flute at an inner surface thereof facing the inside of the chamber. A heater supplies heat concentrated at the flute. The end point detector is optically aligned with the flute of the monitoring window. The geometry of the monitoring window, and the heat from the heater inhibit polymer created during the process within the chamber from depositing at the area of the window through which the process is observed by the end point detector, namely at the flute.

### BACKGROUND OF THE INVENTION

1. Field of the Invention

The present invention relates to a plasma etching apparatus for etching a layer using plasma. More particularly, the present invention relates to an end point detector, of a plasma etching apparatus, and related components for controlling the etching process by detecting a state at which the plasma etching process should be stopped.

2. Description of the Related Art

In general, the manufacturing of a semiconductor device often includes an etching process for etching a desired portion of a material layer. The material layer is exposed through a mask comprising a patterned layer of photoresist. The exposed portion of the material layer is etched away by reacting with an etching solution (wet etching) or an etching gas (dry etching).

A plasma dry etching process is used for etching an insulation film or a metal layer disposed on a wafer. The plasma dry etching process includes steps of mounting the wafer in a sealed chamber of a plasma etching apparatus, and etching an exposed portion of the insulation film or metal layer in the chamber using an etching gas in a plasma state. The insulation film or the metal layer is etched anisotropically in this way. A reactive ion etching process is one type of a dry etching process capable of providing a satisfactory anisotropic etching characteristic. Accordingly, reactive ion etching is mainly used in the forming of fine patterns.

In addition, the plasma etching apparatus is provided with a window in the sealed chamber, and an end point detector for sensing information concerning the progress of the etching process through the window from outside the chamber. A conventional plasma etching apparatus will be described with reference to FIGS. 1 and 2.

The conventional plasma etching apparatus 10 includes a chamber 12 in which the etching process is executed, a transparent monitoring window 14 in one side of the chamber 12, and an end point detector 16 for checking the status of the process in the chamber 12. The end point detector 16 is integrated with the monitoring window 14.

A vacuum pressure atmosphere is produced in the chamber 12. A preprocessed substrate is transferred to the chamber. The substrate comprises, for example, a wafer, a dielectric film or a metal film formed on the wafer, and a mask such as a patterned layer of photoresist formed on the dielectric film or metal film. The substrate is set between upper and lower plate electrodes (not shown) in the chamber 12 with the bottom surface of the wafer W adhered to the lower plate electrode. An etching gas is then fed into the chamber 12 and distributed over the upper surface of the wafer W.

Next, a high frequency power is applied to the upper and lower plate electrodes, and the etching gas interposed between the upper and lower electrode plates is thereby converted into plasma. The plasma reacts with that portion of the layer formed on the wafer and exposed through the pattern mask, whereby the exposed portion is removed.

The reaction of the plasma with the layer being removed causes light of a particular color to be emitted, i.e., one that is peculiar to the type of material being removed. The end point detector 16 detects the progress of the etching process in the chamber 12 by detecting the color of the light that is being emitted during the etching process. For instance, as long as light of a color peculiar to the layer to be removed is being emitted, the end point detector 16 confirms that the etching process is proceeding along.

However, once the desired material is removed, the etching gas reacts with the layer disposed thereunder. At this time, light of a different color, namely, light peculiar to the underlying layer, is emitted. The end point detector 16 recognizes this new color change in the wavelength of the light being given off. Signals from the end point detector 16 are issued to a controller (not shown) that controls the progression of the process. The controller ends the etching process when it receives signals indicative of the above-described change in color of the light being emitted according to the reaction in the chamber 12.

However, polymer is generated in the chamber 12 as a residual of the reaction occurring between the plasma and the layer of material on the wafer. The polymer is deposited at random in the chamber 12. The deposited polymer gradually thickens as the etching processes are continuously carried out, and then not only flake off to contaminate the wafer W in the chamber 12 but also adhere to the inner surface of the monitoring window 14. These particles of polymer thus prevent the end point detector 16 from detecting the etching process end point in a precise and timely manner.

Therefore, respective components of the plasma etching apparatus 10 including the monitoring window 14 and the chamber 12 are cleaned at regular intervals. The cleaning process requires the disassembling and re-assembling of the plasma etching apparatus 10, which results in a lot of downtime. Hence, the prior art plasma etching apparatus has an unsatisfactory operating efficiency.

### SUMMARY OF THE INVENTION

Therefore, one object of the present invention is to provide a plasma etching apparatus having an end point detector that accurately detect the status of a process in a chamber of the apparatus, whereby process errors are prevented.

Another object of the present invention is to provide a plasma etching apparatus that does not have to be cleaned frequently, whereby the apparatus has a high operating efficiency.

In accordance with one aspect of the present invention, a plasma etching apparatus includes a chamber in which a plasma etching process is preformed, a monitoring window made of transparent material, the monitoring window being disposed in one side of the chamber and having a flute that faces the interior of the chamber, a heater for supplying heat concentrated at the flute of the monitoring window, and an optical end point detector for detecting the status of a process occurring in the chamber via the flute of the monitoring window.

The monitoring window also has a protrusion outside the chamber and optically aligned with the end point detector. The heater is positioned to heat the protrusion directly and preferably, at the circumference thereof. The flute may terminate within the window at an innermost end of the protrusion.

A polymer attracting device may also be provided to lead polymer away from the monitoring window. Preferably the polymer attracting device is disposed at the fringe of the monitoring window, either beside or below the window. Preferably, a liner covers the polymer leading part to make the removal of polymer therefrom easy. The polymer attracting device may comprise an electrostatic unit for generating a constant electrostatic force and/or of a cooling unit for creating an atmosphere within the chamber that is lower than that typically prevailing during the plasma etching process.

### BRIEF DESCRIPTION OF THE DRAWINGS

The above and other objects and features of the present invention will become apparent from the following description of the preferred embodiments thereof made in conjunction with the accompanying drawings, of which:

FIG. 1 is a schematic diagram in perspective of a conventional plasma etching apparatus of semiconductor device manufacturing equipment;

FIG. 2 is a schematic diagram in section of a monitoring window and an end point detector of the conventional plasma etching apparatus shown in FIG. 1; and

FIG. 3 is a schematic diagram in section of a monitoring window and an end point detector of a plasma etching apparatus according to the present invention.

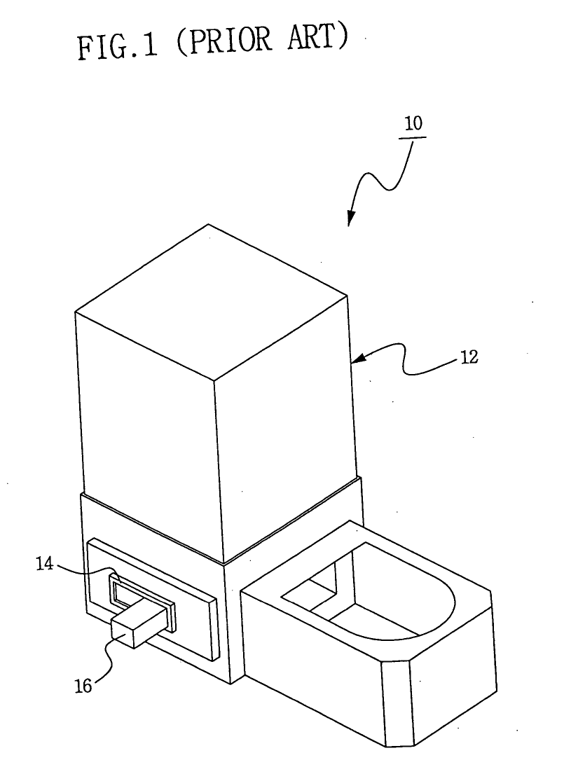

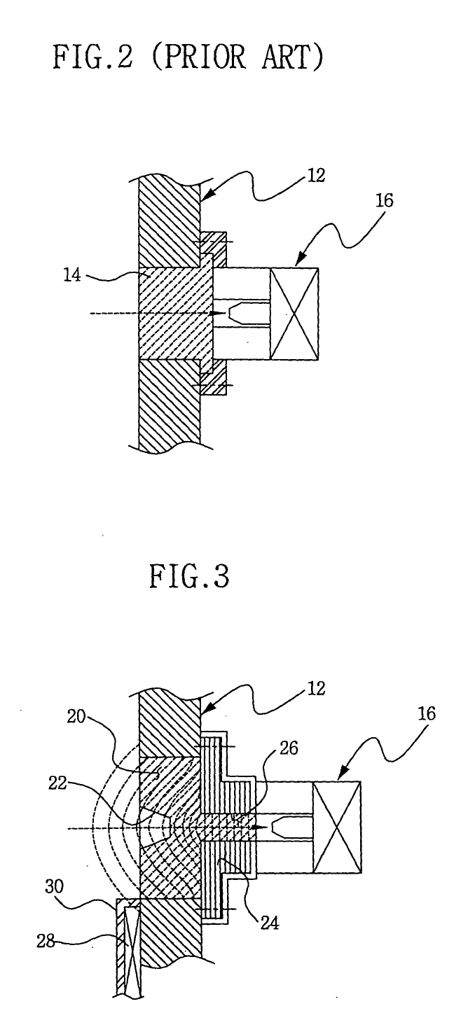

### DETAILED DESCRIPTION OF THE PREFERRED EMBODIMENTS

The present invention will now be described in detail with reference to FIG. 3.

Like the prior art, the plasma etching apparatus includes a process chamber 12, a monitoring window 20 provided in a wall of the chamber 12 as sealed in an airtight manner therewith, and an end point detector 16. The monitoring window 20 is made of a transparent material so that the progression of the process occurring in the chamber 12 can be visually observed from the outside of the chamber 12.

However, as shown in FIG. 3, the monitoring window 20 is provided with a flute 22 that at an inner portion thereof facing into the chamber 12. The flute 20 has a certain depth as taken in an outward direction with respect to the chamber 12. The monitoring window 20 is also provided with a protrusion 26 at an outer side thereof and which protrusion 26 extends in the outward direction. The flute 22 may be so deep as to reach the innermost end of the protrusion 26.

A heater 24 is installed in the apparatus at the outer portion of the monitoring window 20 to heat the monitoring window 20. The heater 24 is centered on the protrusion 26 such that the heat is concentrated at the flute 22 in the monitoring window 20, as shown by the dotted lines. The heat from the heater 24 inhibits polymer from depositing within the chamber 12 on the inner surface of the monitoring window 20.

The end point detector 16 is installed on the monitoring window 20 outside the chamber 12 as aligned with the flute 22, namely, in line with the protrusion 26. Accordingly, the end point detector 16 checks and confirms the status of the etching process in the chamber 12 through the flute 22. The end point detector 16 issues signals to a controller (not shown). The signals are indicative of the color of light that is being emitted in the chamber 12. The controller controls the progression of the process based on these signals.

The monitoring window 20 is also provided with a polymer attracting device 28 that prevents polymer that is generated during the etching process from flowing in an outer circumferential direction towards the monitoring window 20. The polymer attracting device 28 can be disposed beside or beneath the monitoring window 20.

In addition, a liner 30 is provided on the surface of the polymer attracting device 28 such that any polymer may be easily removed from the polymer attracting device 28.

The polymer attracting device 28 can be an electrostatic device, a cooling unit or a combination thereof. In the case of an electrostatic device, the device generates an electrostatic force from power supplied thereto under the control of the controller so as to attract the polymer onto a surface thereof or onto the liner 30. The cooling unit forms a temperature atmosphere lower than interior temperature of the chamber 12, which makes the polymer more likely to adhere thereto than to other higher-temperature portions adjacent the unit, such as the monitoring window 20. Note, the controller can be configured to drive the polymer attracting device 28 at the time the etching process is completed so that the operation of the polymer attracting part 28 does not influences the etching process. On the other hand, the heater 24 is operated continuously during the etching process to prevent the flute 22 and the monitoring window 20 from being polluted by polymer during the process.

In operation, a wafer W is mounted in the chamber 12 on a lower plate electrode disposed beneath an upper plate electrode. Next, an etching gas is supplied into the chamber 12. Subsequently, high frequency power is applied to the upper and lower plate electrodes. Accordingly, the etching gas is converted into plasma to thus react with a portion of a layer exposed through a mask on the wafer. At this time, the end point detector 16 detects the reaction of the process through the monitoring window 20 and issues its detection signals to the controller. As was discussed previously, if polymer generated by the reaction were deposited on some portion of the monitoring window 20, the end point detector 16 could generate erroneous information.

According to the present invention, though, polymer is less likely to accumulate within the flute 22 than on portions of the monitoring window 20 surrounding the flute 22. Also, polymer is less likely to adhere to the monitoring window 20 within the flute 22 due to the high temperature created within the flute by the heater 24. Still further, the polymer attracting device 28 attracts the polymer flowing towards the monitoring window 20 so that only a small amount of polymer is deposited on the monitoring window 20. Accordingly, the status of the process being carried out in the chamber can be checked and confirmed through the monitoring window 20 with a high degree of reliability, thereby preventing process errors from occurring. Moreover, the monitoring window 22 does not have to be cleaned for long periods of time, even though the plasma etching apparatus is operated continuously.

Finally, although the present invention was described in detail above in connection with the preferred embodiments thereof, the scope of the invention is not so limited. Rather, various changes and modifications of the preferred embodiments, as will become apparent to those of ordinary skill in the art, are seen to be within the true spirit and scope of the invention as defined by the appended claims.

What is claimed is:

1. A plasma etching apparatus comprising:
a processing chamber in which a plasma etching process is performed;
a monitoring window of transparent material, said monitoring window being disposed in a side wall of said processing chamber, and said monitoring window having a flute at an inner surface thereof that faces the interior of said processing chamber;
a heater positioned relative to said monitoring window so as provide heat that is concentrated at the flute of said monitoring window; and
an optical detector mounted outside said processing chamber and in alignment with the flute of said monitoring window so as to detect a change in the process occurring in said chamber via the flute.

2. The apparatus of claim 1, wherein said monitoring window has a protrusion at a side thereof remote from the interior of said processing chamber, the protrusion being aligned with said flute in the direction of the depth of said flute and the length of said protrusion, and said heater is positioned to apply heat directly to the protrusion.

3. The apparatus of claim 1, wherein the flute extends to an inner end of said protrusion.

4. The apparatus of claim 1, and further comprising polymer attracting means for attracting polymer within the processing chamber.

5. The apparatus of claim 4, wherein said polymer attracting means is disposed beside or beneath said monitoring window.

6. The apparatus of claim 4, wherein said polymer attracting means is an electrostatic device that generates an electrostatic force in response to an applied control signal.

7. The apparatus of claim 4, wherein said polymer attracting means is a cooling device.
